(19) United States
(12) Patent Application Publication
(10) Pub. No.: US 2024/0203757 A1
(43) Pub. Date: Jun. 20, 2024

(54) CONTROL UNIT AND SEMICONDUCTOR MANUFACTURING EQUIPMENT INCLUDING THE SAME

(71) Applicant: SEMES CO., LTD., Cheonan-si (KR)

(72) Inventors: Hyeong Og MUN, Cheonan-si (KR); Dongwoon PARK, Seoul (KR); Doo Young OH, Cheonan-si (KR); Jae Ho YOO, Seoul (KR)

(73) Assignee: SEMES CO., LTD., Cheonan-si (KR)

(21) Appl. No.: 18/500,963

(22) Filed: Nov. 2, 2023

(30) Foreign Application Priority Data
Dec. 16, 2022 (KR) 10-2022-0176921

(51) Int. Cl. H01L 21/67

(52) U.S. Cl. CPC H01L 21/67017

(57) ABSTRACT

There are provided a control unit and semiconductor manufacturing equipment including the same, which control a damper installed in a main exhaust duct based on exhaust volumes measured from individual exhaust ducts connected to respective units. The semiconductor manufacturing equipment includes: a damper installed in a main exhaust pipe; a first unit treating a substrate and connected to the main exhaust pipe through a first auxiliary exhaust pipe; a second unit treating the substrate and connected to the main exhaust pipe through a second auxiliary exhaust pipe; and a control unit controlling the first and second units, wherein the control unit controls the damper based on exhaust volumes from the first and second units.

### CROSS-REFERENCE TO RELATED APPLICATION

This application claims priority from Korean Patent Application No. 10-2022-0176921 filed on Dec. 16, 2022 in the Korean Intellectual Property Office, and all the benefits accruing therefrom under 35 U.S.C. 119, the contents of which in its entirety are herein incorporated by reference.

### BACKGROUND

### 1. Field

The present disclosure relates to a control unit and semiconductor manufacturing equipment including the same, and more particularly, to a control unit and semiconductor manufacturing equipment including the same, which can be applied to a photolithography process.

### 2. Description of the Related Art

Semiconductor manufacturing processes may be continuously carried out within semiconductor manufacturing equipment and may be classified into front-end processes and back-end processes. Here, the front-end processes refer to processes of forming circuit patterns on a wafer to complete a semiconductor chip, while the back-end processes refer to processes of evaluating the performance of a completed product obtained through the front-end processes.

The semiconductor manufacturing equipment can be installed within a semiconductor manufacturing plant called a fab. Wafers go through various processes such as deposition, photolithography, etching, ion implantation, cleaning, packaging, and inspection, sequentially moving to equipment where each process is performed to produce semiconductors.

The exhaust pressure of the semiconductor manufacturing equipment can be set based on the main exhaust pressure provided by the semiconductor manufacturing plant. Therefore, if the main exhaust pressure provided by the semiconductor manufacturing plant changes, the exhaust pressure of the semiconductor manufacturing equipment may also change.

The main exhaust pressure of the semiconductor manufacturing plant can be manually adjusted by an operator to maintain the exhaust pressure of the semiconductor manufacturing equipment. However, it may take a considerable amount of time for the operator to become aware of changes in the main pressure, make operational plans, and take corrective action. During this time, changes in exhaust pressure may negatively affect the process.

### SUMMARY

Aspects of the present disclosure provide a control unit and semiconductor manufacturing equipment including the same that control a damper installed in a main exhaust duct based on the exhaust volumes measured from individual exhaust ducts connected to respective units.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an aspect of the present disclosure, semiconductor manufacturing equipment includes: a damper installed in a main exhaust pipe; a first unit treating a substrate and connected to the main exhaust pipe through a first auxiliary exhaust pipe; a second unit treating the substrate and connected to the main exhaust pipe through a second auxiliary exhaust pipe; and a control unit controlling the first and second units, wherein the control unit controls the damper based on exhaust volumes from the first and second units.

According to another aspect of the present disclosure, there is provided a control unit for controlling first and second units, wherein the first unit treats a substrate and is connected to a damper, which is installed in a main exhaust pipe through a first auxiliary exhaust pipe, the second unit treats the substrate and is connected to the damper, which is also connected to the main exhaust pipe through a second auxiliary exhaust pipe, the control unit receives pressure resulting from an exhaust volume of the first unit from a first sensor, which is installed in the first auxiliary exhaust pipe, the control unit receives pressure resulting from an exhaust volume of the second unit from a first sensor, which is installed in the second auxiliary exhaust pipe, and the control unit controls the damper based on the received pressures.

According to another aspect of the present disclosure, semiconductor manufacturing equipment includes: a damper installed in a main exhaust pipe; a first unit treating a substrate and connected to the main exhaust pipe through a first auxiliary exhaust pipe; a second unit treating the substrate and connected to the main exhaust pipe through a second auxiliary exhaust pipe; a first shutoff valve installed in the first auxiliary exhaust pipe; a second shutoff valve installed in the second auxiliary exhaust pipe; a first sensor installed in the first auxiliary exhaust pipe and disposed between the first unit and the first shutoff valve; a second sensor installed in the second auxiliary exhaust pipe and disposed between the second unit and the second shutoff valve; and a control unit controlling the first and second units, wherein the control unit controls the damper based on pressures resulting from exhaust volumes measured from the first and second units by the first and second sensors, respectively, the control unit selectively controls the damper based on whether the first and second shutoff valves are open or closed, and the control unit controls the damper if the first and second shutoff valves have the same status regarding whether they are open or closed, and does not control the damper if the first and second shutoff valves have different statuses regarding whether they are open or closed.

It should be noted that the effects of the present disclosure are not limited to those described above, and other effects of the present disclosure will be apparent from the following description.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a first exemplary schematic view illustrating the internal structure of semiconductor manufacturing equipment with a plurality of process chambers;

FIG. 2 is a first exemplary schematic view illustrating the internal structure of the semiconductor manufacturing equipment with a plurality of process chambers;

FIG. 3 is a plan view illustrating the internal configuration of a substrate treating apparatus that performs a heat treatment process on a semiconductor substrate;

FIG. 4 is a cross-sectional view illustrating the internal configuration of the substrate treating apparatus of FIG. 3;

FIG. 5 is a cross-sectional view illustrating the internal configuration of a substrate treating apparatus that performs a development process on a semiconductor substrate;

FIG. 6 is a first exemplary schematic view illustrating a control unit that constitutes the semiconductor manufacturing equipment with a plurality of process chambers;

FIG. 7 is a second exemplary schematic view illustrating the control unit that constitutes the semiconductor manufacturing equipment with a plurality of process chambers;

FIG. 8 is a first exemplary schematic view illustrating the role of the control unit that constitutes the semiconductor manufacturing equipment with a plurality of process chambers;

FIG. 9 is a second exemplary schematic view illustrating explaining the role of the control unit that constitutes the semiconductor manufacturing equipment with a plurality of process chambers;

FIG. 10 is a third exemplary schematic view illustrating the role of the control unit that constitutes the semiconductor manufacturing equipment with a plurality of process chambers;

FIG. 11 is a fourth exemplary schematic view illustrating the role of the control unit that constitutes the semiconductor manufacturing equipment with a plurality of process chambers;

FIG. 12 is a fifth exemplary schematic view illustrating the role of the control unit that constitutes the semiconductor manufacturing equipment with a plurality of process chambers;

FIG. 13 is a sixth exemplary schematic view illustrating the role of the control unit that constitutes the semiconductor manufacturing equipment with a plurality of process chambers;

FIG. 14 is a third exemplary schematic view illustrating the control unit that constitutes the semiconductor manufacturing equipment with multiple process chambers;

FIG. 15 is a seventh exemplary schematic view illustrating the role of the control unit that constitutes the semiconductor manufacturing equipment with a plurality of process chambers;

FIG. 16 is an eighth exemplary schematic view illustrating the role of the control unit that constitutes the semiconductor manufacturing equipment with a plurality of process chambers; and

FIG. 17 is a ninth exemplary schematic view illustrating the role of the control unit that constitutes the semiconductor manufacturing equipment with a plurality of process chambers.

### DETAILED DESCRIPTION

Embodiments of the present disclosure will hereinafter be described with reference to the attached drawings. The same reference numerals are used for the same components in the drawings, and redundant explanations of these will be omitted.

The present disclosure relates to a control unit and a substrate treating apparatus including the same, which can be applied to a photolithography process. The exhaust pressure of semiconductor manufacturing equipment may vary depending on the main exhaust pressure provided by a semiconductor manufacturing plant. The control unit can control a damper installed in a main exhaust duct, based on the exhaust volumes measured from individual exhaust ducts connected to respective units within the semiconductor manufacturing equipment. Further details of the present disclosure will hereinafter be described with reference to the accompanying drawings.

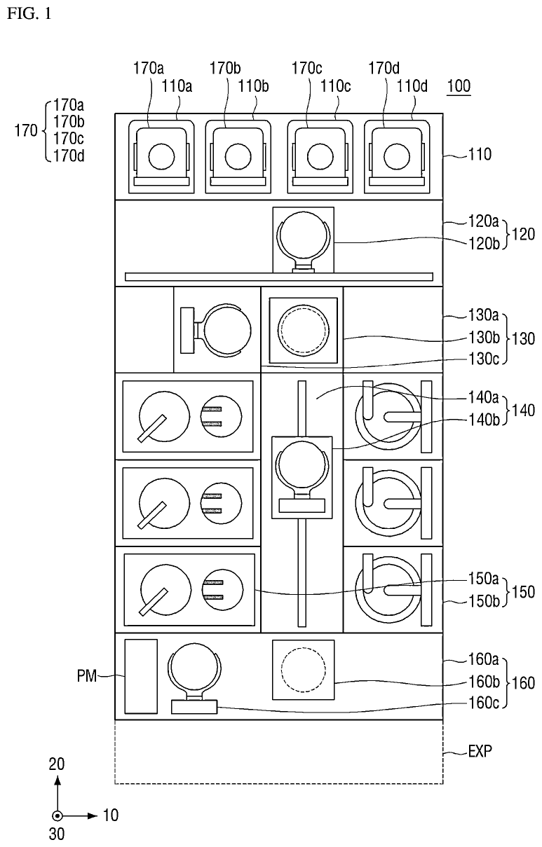

FIG. 1 is a first exemplary schematic view illustrating the internal structure of semiconductor manufacturing equipment with a plurality of process chambers. Referring to FIG. 1, semiconductor manufacturing equipment 100 may be configured to include load port units 110, an index module 120, a buffer module 130, a transfer module 140, process chambers 150, and an interface module 160.

The semiconductor manufacturing equipment 100 is a system for treating a semiconductor substrate through various processes such as coating, exposure, development, and heat treatment. For this purpose, the semiconductor manufacturing equipment 100 may be implemented as a multi-chamber substrate treating system including a plurality of process chambers 150 of the same type or different types, such as a chamber for performing a photoresist coating process, a chamber for performing an exposure process, a chamber for performing a development process, and a chamber for performing a heat treatment process.

The load port units 110 are provided to accommodate containers 170 loaded with multiple semiconductor substrates. The containers 170 may be, for example, front opening unified pods (FOUPs).

The containers 170 may be loaded onto or unloaded from the load port units 110. Also, the semiconductor substrates stored in the containers 170 may be loaded onto or unloaded from the load port units 110.

Although not illustrated in FIG. 1, the containers 170 may be loaded onto or unloaded from the load port units 110 by a container transporting device. Specifically, the containers 170 may be loaded onto the load port units 110 by mounting the containers 170 transported by the container transporting device in the load port units 110. Similarly, the containers 170 may be unloaded from the load port units 110 by gripping the containers 170 placed on the load port units 110 with the container transporting device. Here, the container transporting device may be, for example, an overhead hoist transporter (OHT).

The semiconductor substrates may be loaded onto or unloaded from the containers 170 placed on the load port units 110 by a substrate transfer robot 120b. Once the containers 170 are placed on the load port units 110, the substrate transfer robot 120b may approach the load port units 110 and may retrieve the semiconductor substrates from the containers 170. In this manner, the unloading of the semiconductor substrates may be performed.

Once the treatment of the semiconductor substrates is complete within the process chambers 150, the substrate transfer robot 120b may retrieve remove the semiconductor substrates from the buffer module 130 and place them back onto the containers 170. In this manner, the loading of the semiconductor substrates may be performed.

A plurality of load port units 110 may be disposed in front of the index module 120. For example, a first load port 110a, a second load port 110b, a third load port 110c, and a fourth load port 110d may be disposed in front of the index module 120.

When the load port units 110 are disposed in front of the index module 120, the containers 170 mounted on the load port units 110 may accommodate different types of items. For example, when four load port units 110, i.e., the first, second, third, and fourth load port units 110a, 110b, 110c, and 110d, are provided in front of the index module 120, a first container 170a on the first load port unit 110a to the far left may carry a wafer-type sensor, second and third containers 170b and 170c on the second and third load port units 110b and 110c, respectively, in the middle may carry substrates (or wafers), and a fourth container 170d on the fourth load port unit 110d to the far right may carry a consumable part such as a focus ring or an edge ring.

However, the present embodiment is not limited to this. Alternatively, the first, second, third, and fourth containers 170a, 170b, 170c, and 170d may all carry items of the same type. Yet alternatively, some of the first, second, third, and fourth containers 170a, 170b, 170c, and 170d may carry items of the same type, and the other containers may carry items of different types.

The index module 120 is disposed between the load port units 110 and the buffer module 130 and interfaces the transfer of the semiconductor substrates between the containers 170 on the load port units 110 and the buffer module 130. For this purpose, the index module 120 may include a substrate transfer robot 120b within a module housing 120a. At least one substrate transfer robot 120b may be provided within the module housing 120a.

Although not illustrated in FIG. 1, at least one buffer chamber may be provided within the index module 120. Untreated substrates may be temporarily stored in the buffer chamber before being transferred to the buffer module 130, and treated substrates may also be temporarily stored before being inserted into the containers 170 on the load port units 110. The buffer chamber may be provided on a sidewall that is not adjacent to either the load port units 110 or the buffer module 130, but the present disclosure is not limited thereto. Alternatively, the buffer chamber may be provided on a sidewall adjacent to the buffer module 130.

A front-end module (FEM) may be provided on one side of the buffer module 130. The FEM may include the load port units 110 and the index module 120 and may be implemented as an equipment FEM (EFEM) or a substrate FEM (SFEM).

Meanwhile, the first, second, third, and fourth load port units 110a, 110b, 110c, and 110d may be arranged in a horizontal direction (or a first direction 10), but the present disclosure is not limited thereto. Alternatively, the first, second, third, and fourth load port units 110a, 110b, 110c, and 110d may be stacked in a vertical direction, in which case, the FEM may be configured as, for example, a vertically stacked EFEM.

The buffer module 130 functions as a buffer chamber between the input and output ports of the semiconductor manufacturing equipment 100. The buffer module 130 may include a buffer stage 130b, which temporarily stores the semiconductor substrates. A single buffer stage 130b may be disposed between the index module 120 and the transfer module 140, but the present disclosure is not limited thereto. Alternatively, a plurality of buffer stages 130b may be disposed between the index module 120 and the transfer module 140.

The buffer module 130 may be equipped with not only the buffer stage(s) 130b but also a substrate transfer robot 130c within a module housing 130a. When a plurality of buffer stages 130b are provided, the substrate transfer robot 130c transfers the semiconductor substrates between the buffer stages 130b.

The buffer module 130 may be loaded or unloaded with the semiconductor substrates by a substrate transfer robot 140b of the transfer module 140. The buffer module 130 may also be loaded or unloaded with the semiconductor substrates by the substrate transfer robot 120b of the index module 120.

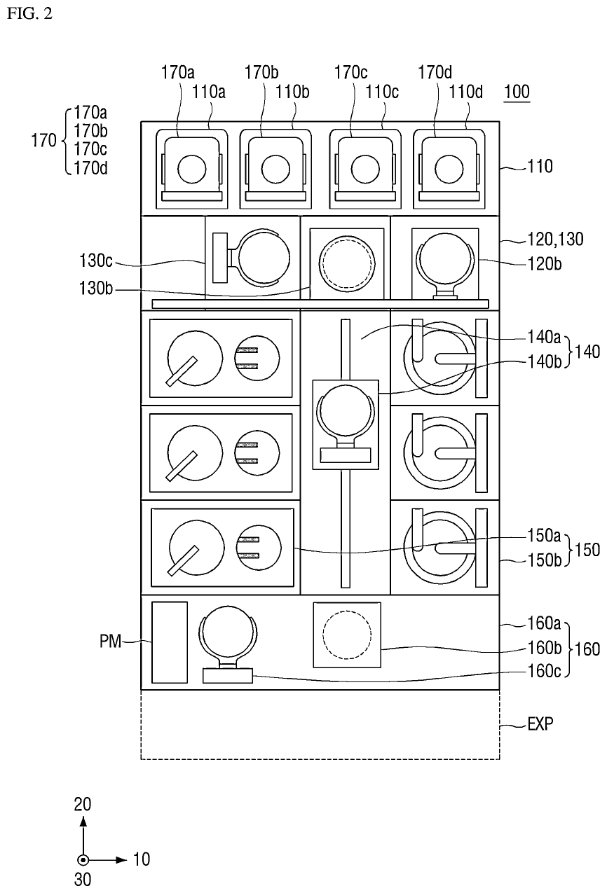

The buffer module 130 may be disposed at the rear end of the index module 120. That is, the buffer module 130 may not necessarily be disposed on the same line as the index module 120, but the present disclosure is not limited thereto. Alternatively, as illustrated in FIG. 2, the buffer module 130 may be disposed on the same line as the index module 120. In this case, the substrate transfer robot 120b of the index module 120, the substrate transfer robot 130c of the buffer module 130, and the buffer stage(s) 130b may be disposed within a single module housing. FIG. 2 is a second exemplary schematic view illustrating the internal configuration of the semiconductor manufacturing equipment with a plurality of process chambers.

Referring back to FIG. 1, the transfer module 140 interfaces the transfer of the semiconductor substrates between the buffer module 130 and the process chambers 150. To this end, the transfer module 140 may be equipped with the substrate transfer robot 140b within the module housing 140a. At least one substrate transfer robot 140b may be provided within the module housing 140a.

The substrate transfer robot 140b transfers untreated substrates from the buffer module 130 to the process chambers 150, or transfers treated substrates from the process chambers 150 to the buffer module 130. For this purpose, sides of the transfer module 140 may be connected to the buffer module 130 and the process chambers 150. Meanwhile, the substrate transfer robot 140b may be provided to be freely movable.

The process chambers 150 processes the semiconductor substrates. A plurality of process chambers 150 may be disposed around the transfer module 140. In this case, the process chambers 150 receive the semiconductor substrates from the transfer module 140, treat (or process) the received semiconductor substrates, and then provide the treated semiconductor substrates back to the transfer module 140.

The process chambers 150 may be cylindrical or polygonal in shape. The process chambers 150 may be formed of alumite with anodized surfaces may be hermetically sealed on the inside. Meanwhile, the process chambers 150 may also be formed in various shapes other than a cylindrical or polygonal shape.

The interface module 160 transfers the semiconductor substrates. The interface module 160 may include a module housing 160a, a buffer stage 160b, and a substrate transfer robot 160c. The buffer stage 160b and the substrate transfer robot 160c are positioned within the module housing 160a. A single buffer stage 160b may be provided, but the present disclosure is not limited thereto. Alternatively, a plurality of buffer stages 160b may be provided, in which case, the buffer stages 160b may be a predetermined distance apart from one another and may be stacked on one another.

The substrate transfer robot 160c transports the semiconductor substrates between the buffer stage 160b and an exposure device EXP. The buffer stage 160b temporarily stores semiconductor substrates yet to be processed by the exposure device EXP before transferring them to the exposure device EXP, or temporarily stores semiconductor substrates that have processed by the exposure device EXP. Only the aforementioned buffers and robots may be provided in the interface module 160 without any chambers for performing particular processes on the semiconductor substrates.

Meanwhile, a purge module PM may be provided in the module housing 160a of the interface module 160, but the present disclosure is not limited thereto. Alternatively, the purge module PM may also be provided at various other locations such as where the exposure device EXP is connected at the rear end of the interface module 160 or on a side of the interface module 160.

As previously described, the buffer stage(s) 130b may be provided in the buffer module 130, and the buffer stage(s) 160b may be provided in the interface module 160. The buffer stage(s) 130b may be defined as a first buffer stage or first buffer stages, and the buffer stage(s) 160b may be defined as a second buffer stage or second buffer stages to distinguish between the buffer stage(s) 130b and the buffer stage(s) 160b.

Also, as previously explained, the substrate transfer robot 120b may be provided in the index module 120, the substrate transfer robot 130c may be provided in the buffer module 130, the substrate transfer robot 140b may be provided in the transfer module 140, and the substrate transfer robot 160c may be provided in the interface module 160. The substrate transfer robots 120b, 130c, 140b, and 160c are defined as first, second, third, and fourth transfer robots, respectively, to distinguish between the substrate transfer robots 120b, 130c, 140b, and 160c.

The semiconductor manufacturing equipment 100 may be formed to have an in-line platform structure, as illustrated in FIG. 1. In this case, the process chambers 150 may be arranged in an in-line manner with respect to the transfer module 140, and different types of process chambers 150 may be arranged in series on both sides of the transfer module 140 to correspond to each other. However, the present disclosure is not limited to this. Alternatively, the semiconductor manufacturing equipment 100 may be formed to have a cluster platform structure or a quad platform structure.

Substrate treating apparatuses, i.e., the process chambers 150 provided in the semiconductor manufacturing equipment 100, will hereinafter be described. As previously described, the semiconductor manufacturing equipment 100 may include a plurality of process chambers 150, which are arranged in an in-line manner with respect to the transfer module 140. In this case, different types of process chambers 150 may be arranged in series on both sides of the transfer module 140 to correspond to each other. One type of process chamber 150 may be a substrate treating apparatus 150a that performs a heat treatment process on a substrate, and another type of process chamber 150 may be a substrate treating apparatus 150b that performs a coating or development process on a substrate.

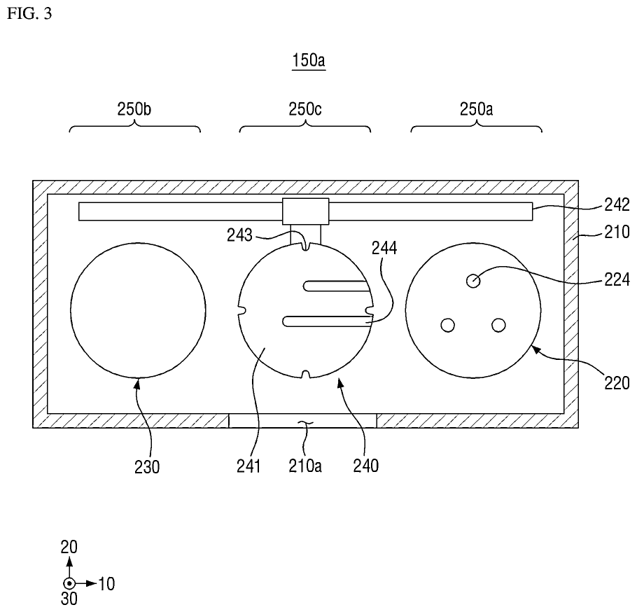

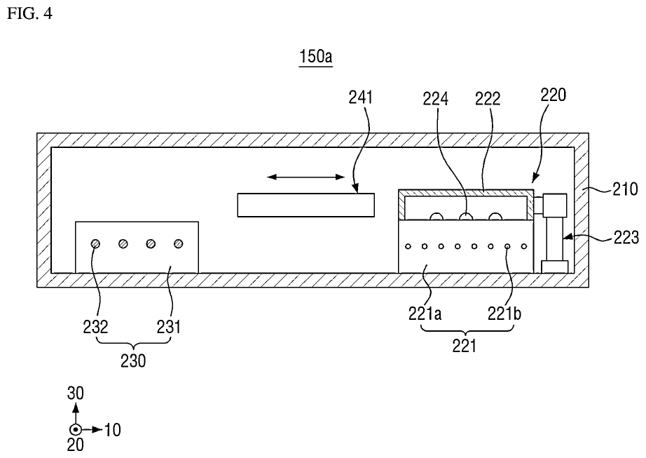

The substrate treating apparatus 150a, which performs a heat treatment process on a substrate, will hereinafter be described. FIG. 3 is a plan view illustrating the internal configuration of a substrate treating apparatus that performs a heat treatment process on a semiconductor substrate. FIG. 4 is a cross-sectional view illustrating the internal configuration of the substrate treating apparatus of FIG. 3.

Referring to FIGS. 3 and 4, the substrate treating apparatus 150a may be configured to include a chamber housing 210, a heating unit 220, a cooling unit 230, and a transfer unit 240.

The substrate treating apparatus 150a is an apparatus for heating and cooling a substrate (for example, a wafer). When performing a photolithography process on the substrate, the substrate treating apparatus 150a may heat and cool the substrate. For example, the substrate treating apparatus 150a may be provided as a bake chamber that performs a bake process.

A photolithography process may include coating, exposure, development, and baking processes. In this case, the substrate treating apparatus 150a may heat and/or cool the substrate before or after performing the coating process, i.e., before or after applying photoresist (PR) to the substrate. Alternatively, the substrate treating apparatus 150a may heat and/or cool the substrate before or after the exposure process. Alternatively, the substrate treating apparatus 150a may heat and/or cool the substrate before or after the development process.

The chamber housing 210 provides space for treating the substrate. The chamber housing 210 may be installed to accommodate the heating unit 220, the cooling unit 230, and the transfer unit 240 to enable heating and cooling treatments for the substrate.

An inlet 210a for the substrate may be formed on a sidewall of the chamber housing 210. At least one inlet 210a may be provided in the chamber housing 210. The inlet 210a may always be open. Alternatively, although not illustrated in FIG. 4, the inlet 210a may also be opened and closed through a door.

The internal space of the chamber housing 210 may be divided into a heating zone 250a, a cooling zone 250b, and a buffer zone 250c. Here, the heating zone 250a refers to the area where the heating unit 220 is located, and the cooling zone 250b refers to the area where the cooling unit 230 is located. The heating zone 250a may be provided with the same width as, or a larger width than, the heating unit 220. Similarly, the cooling zone 250b may be provided with the same width as, or a larger width than, the cooling unit 230.

The buffer zone 250c refers to the area where a transfer plate 241 of the transfer unit 240 is located. The buffer zone 250c may be provided between the heating zone 250a and the cooling zone 250b. When the buffer zone 250c is provided in this manner, the heating unit 220 and the cooling unit 230 may be sufficiently spaced apart to prevent thermal interference therebetween. The buffer zone 250c may be provided with the same width as, or a larger width than, the transfer plate 241.

When the heating unit 220, the cooling unit 230, and the transfer unit 240 are disposed on the heating zone 250a, the cooling zone 250b, and the buffer zone 250c, respectively, within the chamber housing 210, the cooling unit 230, the transfer unit 240, and the heating unit 220 may be sequentially arranged in the first direction 10, but the present disclosure is not limited thereto. Alternatively, the heating unit 220, the transfer unit 240, and the cooling unit 230 may be sequentially arranged in the first direction 10.

The heating unit 220 is for heating the substrate. The heating unit 220 may provide gas onto the substrate when heating the substrate. For example, the heating unit 220 may provide a hexamethyldisilane gas, thereby improving the adhesion rate of PR on the substrate.

The heating unit 220 may be configured to include a heating plate 221, a cover module 222, and a driving module 223 for heating the substrate.

The heating plate 221, which is also referred to as a hot plate, applies heat to the substrate. For this purpose, the heating plate 221 may be configured to include a body part 221a and heaters 221b.

The body part 221a supports the substrate when applying heat. The body part 221a may be formed with the same diameter as, or a larger diameter than, the substrate.

The body part 221a may be formed of a metal with excellent heat resistance or a metal with excellent fire resistance. For example, the body part 221a may be formed of a ceramic material such as aluminum oxide (Al₂O₃) or aluminum nitride (AlN).

Meanwhile, although not illustrated in FIGS. 3 and 4, the body part 221a may be equipped with a plurality of vacuum holes formed to penetrate in the vertical direction (or a third direction 30). Here, the vacuum holes may fix the substrate in place when applying heat by creating a vacuum pressure.

Also, although not illustrated in FIGS. 3 and 4, the body part 221a may be divided into an upper plate and a lower plate disposed below the upper plate. Here, the substrate may be positioned on the upper plate, and the heaters 221b may be installed within the lower plate.

The heaters 221b applies heat to the substrate on the body part 221a. A plurality of heaters 221b may be installed within the body part 221a. The heaters 221b may be configured as heating resistors (for example, heating elements) through which a current is applied. However, the heaters 221b may be of any other form as long as they can effectively apply heat to the substrate on the body part 221a.

The cover module 222 is formed to cover the top of the heating plate 221 when the heating plate 221 heats the substrate. The cover module 222 may move in the vertical direction (or the third direction 30) under the control of the driving module 223 to open and close the top of the heating plate 221.

The driving module 223 is for moving the cover module 222 in the vertical direction (or the third direction 30). When the substrate is securely positioned on the top of the heating plate 221 for heat treatment, the driving module 223 may move the cover module 222 in a downward direction toward the chamber housing 210 to completely cover the top of the heating plate 221. Also, once the heat treatment of the substrate is complete, the driving module 223 may move the cover module 222 in an upward direction, thereby exposing the top of the heating plate 221 to allow the transfer unit 240 to move the substrate to the cooling unit 230.

The cooling unit 230 cools the substrate that has been heated by the heating unit 220. For this purpose, the cooling unit 230 may be configured to include a cooling plate 231 and cooling elements 232.

When high-temperature heat is applied to the substrate via the heating unit 220, warpage of the substrate may occur. The cooling unit 230 may restore the substrate to its original state by cooling the substrate down to an appropriate temperature.

The cooling elements 232 are formed within the cooling plate 231. The cooling elements 232 may be provided as flow paths through which a cooling fluid flows.

The transfer unit 240 moves the substrate to either the heating unit 220 or the cooling unit 230. For this purpose, the transfer unit 240 may have a hand coupled with a transfer plate 241 at its end and may move the transfer plate 241 along a guide rail 242 toward where the heating unit 220 or the cooling unit 230 is located.

The transfer plate 241, which is disc-shaped, may be formed to have a diameter corresponding to the substrate. The transfer plate 241 may include a plurality of notches 243, which are formed along the edge of the transfer plate 241, and a plurality of guide grooves 244, which are on the top surface of the transfer plate 241 and have a slit shape.

The guide grooves 244 may be formed to extend from the end of the transfer plate 241 toward the center of the transfer plate 241. The guide grooves 244 may be spaced apart in the same direction (or the first direction 10). The guide grooves 244 may prevent interference between the transfer plate 241 and lift pins 224 when the substrate is transferred between the transfer plate 241 and the heating unit 220.

The substrate is heated when it is directly placed on the heating plate 221 and is cooled when the transfer plate 241 where the substrate is placed comes into contact with the cooling plate 231. To facilitate efficient heat transfer between the cooling plate 231 and the substrate, the transfer plate 241 may be formed of a material with excellent thermal conductivity (e.g., a metal).

Meanwhile, although not illustrated in FIGS. 3 and 4, the transfer unit 240 may receive the substrate from an externally installed substrate transfer robot through the inlet 210a of the chamber housing 210.

The lift pins 224 have a free-fall structure and serve the role of lifting up or down the substrate on the heating plate 221. After receiving the substrate from the transfer unit 240, the lift pins 224 may descend to secure the substrate on the heating plate 221 for a baking process. Once the baking process is complete, the lift pins 224 may ascend to transfer the substrate back to the transfer unit 240. The lift pins 224 may be formed to penetrate the heating plate 221 in the vertical direction (or the third direction 30).

The lift pins 224, like the body part 221a, may be formed of a material with excellent heat resistance. In this case, the lift pins 224 may be formed of the same metal as the body part 221a, but alternatively, the lift pins 224 and the body part 221a may also be formed of different metals.

For example, the lift pins 224 may be driven using a linear motor (LM) guide system and may be controlled by a plurality of cylinders connected to the LM guide system. The LM guide system has the advantage of being able to cope with high temperatures and vibrations.

Meanwhile, a plurality of lift pins 224 may be installed on the heating plate 221 to stably support the substrate when lifting up the substrate from the heating plate 221. For example, as illustrated in FIGS. 3 and 4, three lift pins 224 may be installed.

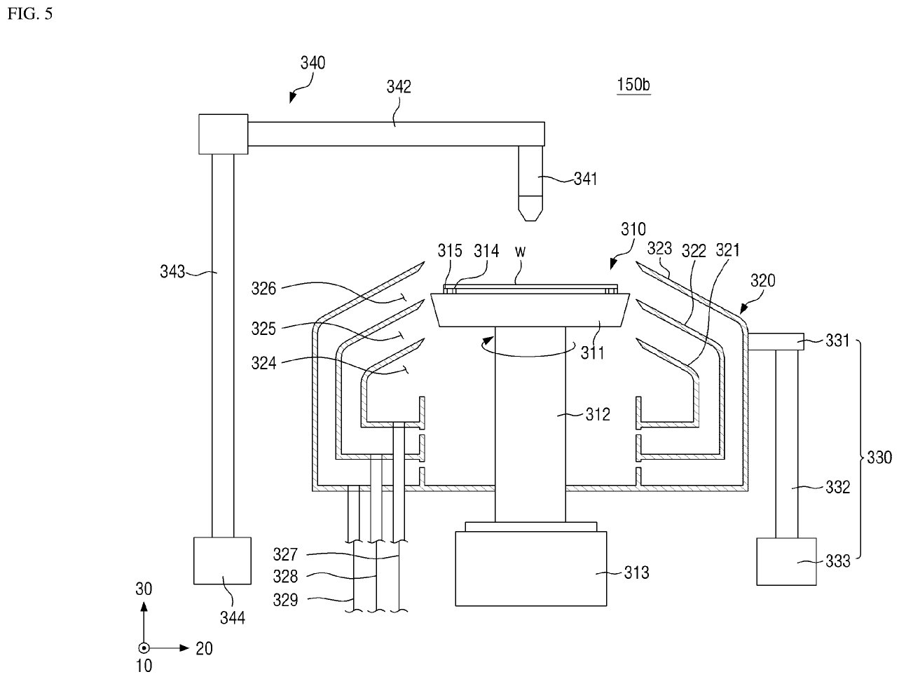

The substrate treating apparatus 150b will hereinafter be described in further detail. FIG. 5 is a cross-sectional view illustrating the internal configuration of a substrate processing apparatus that performs a development process on a semiconductor substrate.

The substrate treating apparatus 150b is an apparatus that treats a substrate W using chemical solutions. The substrate treating apparatus 150b may use the chemical solutions to remove photoresist from the substrate W. The substrate treating apparatus 150b may be implemented as a cleaning process chamber that cleans the substrate W using the chemical solutions.

The substrate treating apparatus 150b may also be implemented as an apparatus that performs a coating process on the substrate W. In this case, the substrate treating apparatus 150b may form photoresist on the substrate W using the chemical solutions.

Here, the chemical solutions may be liquid substances (e.g., organic solvents) or gaseous substances. The chemical solutions may have high volatility, generate fumes, or have high viscosity and are thus residue-prone. The chemical solutions may be selected from among materials that include isopropyl alcohol (IPA) components, sulfuric acid components (e.g., sulfuric peroxide mixture (SPM) containing sulfuric acid and hydrogen peroxide), ammonia components (e.g., SC-1 (i.e., H₂O₂+NH₄OH)), hydrofluoric acid components (e.g., diluted hydrogen fluoride (DHF)), and phosphoric acid components. Chemical solutions for treating the substrate W may be defined as substrate treating solutions.

When the substrate treating apparatus 150b is applied for a cleaning process, the substrate treating apparatus 150b may rotate the substrate W using a spin head and may provide a chemical solution onto the surface of the substrate W using a nozzle. As illustrated in FIG. 5, when configured as a liquid treating chamber, the substrate treating apparatus 150b may include a substrate support unit 310, a treating solution recovery unit 320, a lifting unit 330, and a spraying unit 340.

The substrate support unit 310 is a module that supports the substrate W. The substrate support unit 310 may rotate the substrate W in a direction perpendicular to the third direction 30, for example, in the first direction 10 or a second direction 20, during the treatment of the substrate W. The substrate support unit 310 may be disposed within the solution recovery unit 320 to recover substrate treating solutions used during the treatment of the substrate W.

The substrate support unit 310 may be configured to include a spin head 311, a rotary shaft 312, a rotary driving module 313, support pins 314, and guide pins 315.

The spin head 311 rotates along the direction of rotation of the rotary shaft 312, which is perpendicular to the third direction 30. The spin head 311 may be provided to have the same shape as the substrate W, but the present disclosure is not limited thereto. The spin head 311 may also be provided to have a different shape from the substrate W.

The rotary shaft 312 generates a rotational force using energy provided by the rotary driving module 313. The rotary shaft 312 may be coupled to both the rotary driving module 313 and the spin head 311 and may deliver the rotational force from the rotary driving module 313 to the spin head 311. The spin head 311 rotates along with the rotary shaft 312, in which case, the substrate W attached to the spin head 311 may also rotate with the spin head 311.

The support pins 314 and the guide pins 315 fix the substrate W on the spin head 311. The support pins 314 support the bottom surface of the substrate W on the spin head 311, while the guide pins 315 support the side surfaces of the substrate W. Multiple support pins 314 and multiple guide pins 315 may be installed on the spin head 311.

The support pins 314 may be disposed with a circular ring shape as a whole. As a result, the support pins 314 can support the bottom surface of the substrate W at a predetermined distance from the top of the spin head 311.

The guide pins 315, which are chucking pins, may support the substrate W in place and prevent the substrate W from being detached from its original position when the spin head 311 rotates.

The treating solution recovery unit 320 recovers the substrate treating solutions used to treat the substrate W. The treating solution recovery unit 320 may be installed around the substrate support unit 310, providing space for performing a treating operation on the substrate W.

After the substrate W is attached and fixed on the substrate support unit 310 and starts rotating under the control of the substrate support unit 310, the spraying unit 340 may inject substrate treating solutions onto the substrate W under the control of a control unit. Then, due to the centrifugal force generated by the rotational force of the substrate support unit 310, the substrate treating solutions ejected onto the substrate W may be dispersed in the directions where the treating solution recovery unit 320 is located. In this case, the treating solution recovery unit 320 may recover the substrate treating solutions when the substrate treating solutions flow into its interior through inflow ports (i.e., a first opening 324 of a first recovery tank 321, a second opening 325 of a second recovery tank 322, and a third opening 326 of a third recovery tank 323).

The treating solution recovery unit 320 may be configured include multiple recovery tanks. For example, the treating solution recovery unit 320 may include three recovery tanks. In this case, the substrate treating solution used to treat the substrate W may be separated and recovered, enabling the recycling of the substrate treating solutions.

The treating solution recovery unit 320 may include three recovery tanks, i.e., the first, second, and third recovery tanks 321, 322, and 323. The first, second, and third recovery tanks 321, 322, and 323 may be implemented, for example, as bowls.

The first, second, and third recovery tanks 321, 322, and 323 may recover different substrate treating solutions. For example, the first recovery tank 321 may recover a rinse liquid (e.g., deionized (DI) water), the second recovery tank 322 may recover a first chemical solution, and the third recovery tank 323 may recover a second chemical solution.

The first, second, and third recovery tanks 321, 322, and 323 may be connected to recovery lines 327, 328, and 329 extending in a downward direction (or the third direction 30) from the bottom surfaces of the first, second, and third recovery tanks 321, 322, and 323. First, second, and third treating solutions recovered through the first, second, and third recovery tanks 321, 322, and 323, respectively, may be processed and made reusable through a treating solution regeneration system (not illustrated).

The first, second, and third recovery tanks 321, 322, and 323 may be provided in a circular ring shape surrounding the substrate support unit 310. The size of the first, second, and third recovery tanks 321, 322, and 323 may gradually increase from the first recovery tank 321 to the third recovery tank 323 (e.g., in the second direction 20). When the distance between the first and second recovery tanks 321 and 322 is defined as a first gap and the distance between the second and third recovery tanks 322 and 323 is defined as a second gap, the first gap may be the same as the second gap, but the present disclosure is not limited thereto. Alternatively, the first gap may differ from the second gap. In other words, the first gap may be larger or smaller than the second gap.

The lifting unit 330 is for rectilinearly moving the treating solution recovery unit 320 in the vertical direction (or the third direction 30). The lifting unit 330 may adjust the relative height of the treating solution recovery unit 320 with respect to the substrate support unit 310 (or the substrate W).

The lifting unit 330 may be configured to include a bracket 331, a first support shaft 332, and a first driving module 333.

The bracket 331 is fixed to the outer wall of the treating solution recovery unit 320. The bracket 331 may be coupled with the first supporting axis 332, which moves in the vertical direction under the control of the first driving module 333.

When the substrate W is attached to the substrate support unit 310, the substrate support unit 310 may be positioned above the treating solution recovery unit 320. Similarly, when the substrate W is detached from the substrate support unit 310, the substrate support unit 310 may also be positioned above the treating solution recovery unit 320. In such cases, the lifting unit 330 may lower the treating solution recovery unit 320.

When the substrate W is being treated, the substrate treating solutions ejected onto the substrate W may be recovered into one of the first, second, and third recovery tanks 321, 322, and 323, depending on their types. Even in this case, the lifting unit 330 may lift or lower the treating solution recovery unit 320 to each desired position. For example, if the first treating solution is used, the lifting unit 330 may lift the treating solution recovery unit 320 to a height corresponding to the first opening 324 of the first recovery tank 321.

Meanwhile, the lifting unit 330 may adjust the relative height of the treating solution recovery unit 320 with respect to the substrate support unit 310 (or the substrate W) by rectilinearly moving the substrate support unit 310 in the vertical direction.

However, the present disclosure is not limited to this. Alternatively, the lifting unit 330 may adjust the relative height of the treating solution recovery unit 320 with respect to the substrate support unit 310 (or the substrate W) by rectilinearly moving both the substrate support unit 310 and the treating solution recovery unit 320 at the same time in the vertical direction.

The spraying unit 340 is a module that supplies substrate treating solutions onto the substrate W during the treatment of the substrate W. At least one spraying unit 340 may be installed within the substrate treating apparatus 150b. When a plurality of spraying units 340 are installed within the substrate treating apparatus 150b, the spraying units 340 may inject different substrate treating solutions onto the substrate W.

The spraying unit 340 may be configured to include a nozzle structure 341, a nozzle support module 342, a second support shaft 343, and a second driving module 344.

The nozzle structure 341 is installed at one end of the nozzle support module 342. The nozzle structure 341 may be moved to a processing position or a standby position by the second driving module 344.

Here, the processing position refers to a region above the substrate W, while the standby position refers to regions other than the processing position. To eject a substrate treating solution onto the substrate W, the nozzle structure 341 may be moved to the processing position. Then, after ejecting the substrate treating solution onto the substrate W, the nozzle structure 341 may move away from the processing position to the standby position.

The nozzle support module 342 supports the nozzle structure 341. The nozzle support module 342 may extend in a direction corresponding to the length direction of the spin head 311. In other words, the length direction of the nozzle support module 342 may be provided along the second direction 20.

The nozzle support module 342 may be coupled to the second support shaft 343, which extends in a vertical direction with respect to its length direction. The second support shaft 343 may extend in a direction corresponding to the height direction of the spin head 311. In other words, the length direction of the second support shaft 343 may be provided along the third direction 30.

The second driving module 344 is a module that rotates and elevates the second support shaft 343 and the nozzle support module 342, which is linked with the second support shaft 343. As a result, the nozzle structure 341 may be moved to the processing position or the standby position.

Although not explicitly illustrated in FIG. 5, the substrate treating apparatus 150b may further include a substrate treating solution supply module. The substrate treating solution supply module provides a substrate treating solution into the substrate treating apparatus 150b. To this end, the substrate treating solution supply module may be connected to the spraying unit 340 and may operate under the control of the control device.

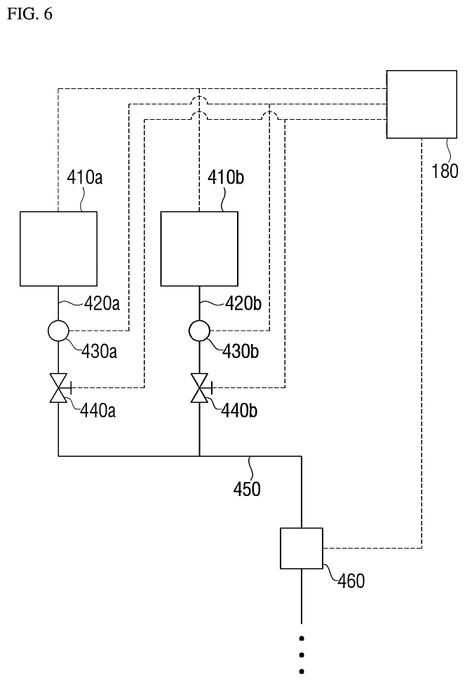

FIG. 6 is a first exemplary schematic view illustrating a control unit that constitutes the semiconductor manufacturing equipment with a plurality of process chambers.

Referring to FIG. 6, a control unit 180 controls the overall operations of the components of the semiconductor manufacturing equipment 100. For example, the control unit 180 may control substrate insertion and withdrawal performed by the substrate transport robots 120b, 130c, and 140b of the index module 120, the buffer module 130, and the transfer module 140 and may also control substrate processing in the processing chambers 150. Additionally, the control unit 180 may also control the operation of the substrate treating solution supply module and the operation of each unit provided in each of the process chambers 150.

The control unit 180 may include: a process controller, which consists of a microprocessor (or a computer) that executes the control of the semiconductor manufacturing equipment 100; a user interface, which includes a keyboard for an operator to input commands and manage the semiconductor manufacturing equipment 100 and a display to visualize the operating status of the semiconductor manufacturing equipment 100; and a memory unit, which stores control programs for executing processes under the control of the process controller or programs (or processing recipes) for executing processes in the semiconductor manufacturing equipment 100 based on various data and processing conditions. The user interface and the memory unit may be connected to the process controller. The processing recipes may be stored on a storage medium within the memory unit, and the storage medium may be a hard disk, a removable disc such as a compact disc read-only memory (CD-ROM) or a digital versatile disc (DVD), or a semiconductor memory such as a flash memory.

As previously described, the exhaust pressure of each unit installed in a semiconductor manufacturing plant may be set based on the main exhaust pressure provided by the semiconductor manufacturing plant, which can be manually adjusted by an operator. However, this type of method has the following problems.

First, it may take considerable time for the operator to recognize fluctuations in the main pressure, make operational plans, and take corrective action. During this time, negative impacts may occur on the process due to changes in exhaust pressure.

Second, when installing a damper that operates automatically in each unit of the semiconductor manufacturing equipment 100 for control, exhaust pressure interference occurs between the units of the semiconductor manufacturing equipment 100, making it difficult to achieve precise pressure control.

Third, when controlling a main damper with the main exhaust pressure, the main exhaust pressure fluctuates depending on the process status of each unit of the semiconductor manufacturing plant, again making it difficult to achieve precise pressure control.

The control unit 180 may control a damper installed in the main exhaust duct based on the exhaust volumes measured from individual exhaust ducts connected to the respective units of the semiconductor manufacturing equipment 100. Further details will hereinafter be explained below.

The control unit 180 may control a plurality of units. For example, the control unit 180 may control both first and second units 410a and 410b. In this example, the first and second units 410a and 410b may be process chambers of different types. The first unit 410a may be the substrate processing apparatus 150a, i.e., a process chamber 150a that performs a heat treatment process on the substrate W. The second unit 410b may be the substrate processing apparatus 150b, i.e., a process chamber 150b that performs a coating or development process on the substrate W.

However, the present disclosure is not limited to this. Alternatively, the first and second units 410a and 410b may be process chambers of the same type. For example, the semiconductor manufacturing equipment 100 may include two substrate processing apparatuses 150b. In this example, the first unit 410a may be one of the two substrate processing apparatuses 150b, and the second unit 410b may be the other substrate processing apparatuses 150b.

Alternatively, the first and second units 410a and 410b may be different modules within the same process chamber. For example, if the process chamber where the first and second units 410a and 410b are disposed is the substrate processing apparatus 150a, the first unit 410a may be the heating unit 220, and the second unit 410b may be the cooling unit 230.

In the semiconductor manufacturing equipment 100, a plurality of units may be individually connected to a plurality of respective exhaust pipes. In other words, the plurality of units may be connected one-to-one to the plurality of respective exhaust pipes. Specifically, the first unit 410a may be connected to a first auxiliary exhaust pipe 420a, and the second unit 410b may be connected to a second auxiliary exhaust pipe 420b.

The control unit 180 may control sensors installed in the first and second exhaust pipes 420a and 420b. The control unit 180 may control a first sensor 430a, which is installed in the first auxiliary exhaust pipe 420a. Furthermore, the control unit 180 may control a second sensor 430b, which is installed in the second auxiliary exhaust pipe 420b. The first and second sensors 430a and 430b may be sensors with identical functions. The first and second sensors 430a and 430b may be sensors that measure exhaust pressure.

The control unit 180 may control valves installed in the respective exhaust pipes. The control unit 180 may control a first shutoff valve 440a, which is installed in the first auxiliary exhaust pipe 420a. Furthermore, the control unit 180 may control a second shutoff valve 440b, which is installed in the second auxiliary exhaust pipe 420b. The first and second shutoff valves 440a and 440b may be valves with identical functions. The first and second shutoff valves 440a and 440b may be shutoff valves that open and close the first and second exhaust pipes 420a and 420b, respectively.

The exhaust pipes connected to the respective units may be connected to a main exhaust pipe 450 for external discharge. A damper 460 may be installed in the main exhaust pipe 450. The damper 460 may control the flow rate of fluid within the main exhaust pipe 450. The control unit 180 may control the damper 460, which is installed in the main exhaust pipe 450.

As previously mentioned, the control unit 180 may control the first and second units 410a and 410b. The control unit 180 may control the first and second units 410a and 410b to receive process status information from the first and second units 410a and 410b.

Additionally, the control unit 180 may control the first and second sensors 430a and 430b. The first and second sensors 430a and 430b may measure the pressure of fluid flowing through the first and second auxiliary exhaust pipes 420a and 420b. The control unit 180 may control the first and second sensors 430a and 430b to receive information regarding the pressure of fluid flowing through the first and second auxiliary exhaust pipes 420a and 420b.

Additionally, the control unit 180 may control the first shutoff valve 440a, the second shutoff valve 440b, and the damper 460. The first shutoff valve 440a, the second shutoff valve 440b, and the damper 460 may open and close the first auxiliary exhaust pipe 420a, the second auxiliary exhaust pipe 420b, and the main exhaust pipe 450, respectively, to control the flow of fluid. The control unit 180 may control the first shutoff valve 440a, the second shutoff valve 440b, and the damper 460 to receive valve status information from the first shutoff valve 440a, the second shutoff valve 440b, and the damper 460.

As previously explained, sensors and valves may be installed in the respective auxiliary exhaust pipes. That is, the first sensor 430a and the first shutoff valve 440a may be installed in the first auxiliary exhaust pipe 420a, and the second sensor 430b and the second shutoff valve 440b may be installed in the second auxiliary exhaust pipe 420b.

In this case, the first sensor 430a may be positioned closer to the first unit 410a compared to the first shutoff valve 440a, and the first shutoff valve 440a may be positioned closer to the main exhaust pipe 450 compared to the first sensor 430a. Similarly, the second sensor 430b may be positioned closer to the second unit 410b compared to the second shutoff valve 440b, and the second shutoff valve 440b may be positioned closer to the main exhaust pipe 450 compared to the second sensor 430b.

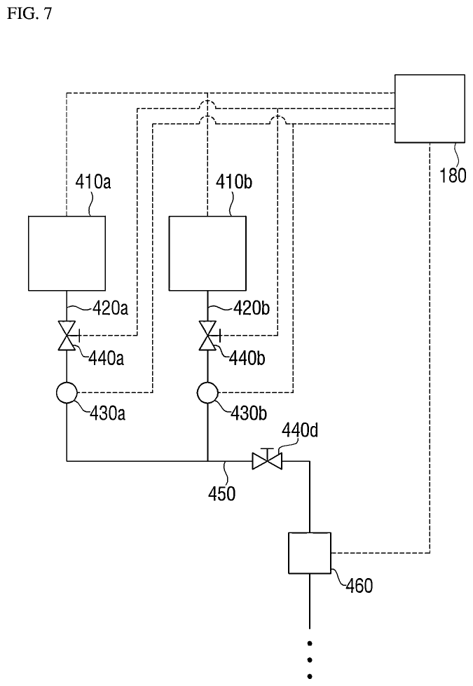

However, the present disclosure is not limited to this. Alternatively, as illustrated in FIG. 7, the first sensor 430a may be positioned closer to the main exhaust pipe 450 compared to the first shutoff valve 440a, and the first shutoff valve 440a may be positioned closer to the first unit 410a compared to the first sensor 430a. In this case, the second sensor 430b may be positioned closer to the main exhaust pipe 450 compared to the second shutoff valve 440b, and the second shutoff valve 440b may be positioned closer to the second unit 410b compared to the second sensor 430b. Also, in this case, at least one additional shutoff valve 440d may be installed between the damper 460 and either of the first and second sensors 430a and 430b. FIG. 7 is a second exemplary schematic view illustrating the control unit that constitutes the semiconductor manufacturing equipment with a plurality of process chambers.

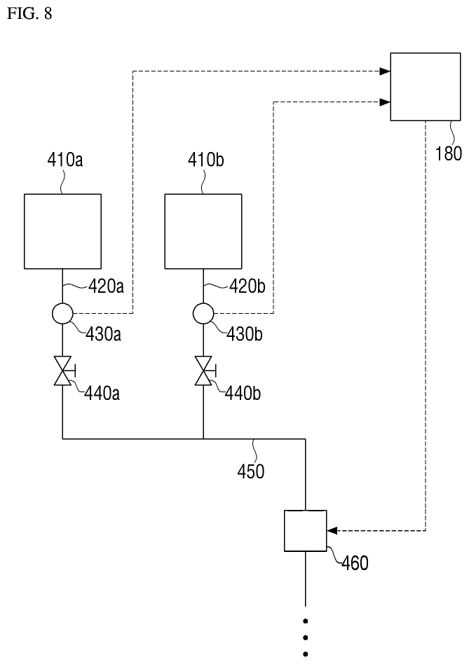

The control unit 180 may control the damper 460, which is installed in the main exhaust duct based on the exhaust volumes measured from the individual exhaust ducts connected to the respective units. That is, referring to FIG. 8, the control unit 180 may control the damper 460 based on the measurement results from the first and second sensors 430a and the 430b, which are installed in the first and second auxiliary exhaust pipes 420a and 420b, respectively, and may thereby control the flow rate of the fluid within the main exhaust pipe 450. FIG. 8 is a first exemplary schematic view illustrating the role of the control unit that constitutes the semiconductor manufacturing equipment with a plurality of process chambers.

The control unit 180 may use information regarding the first and second shutoff valves 440a and 440b when controlling the damper 460 based on the measurement results from the first and second sensors 430a and 430b.

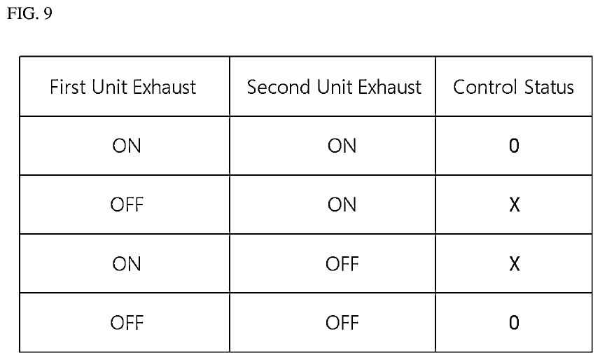

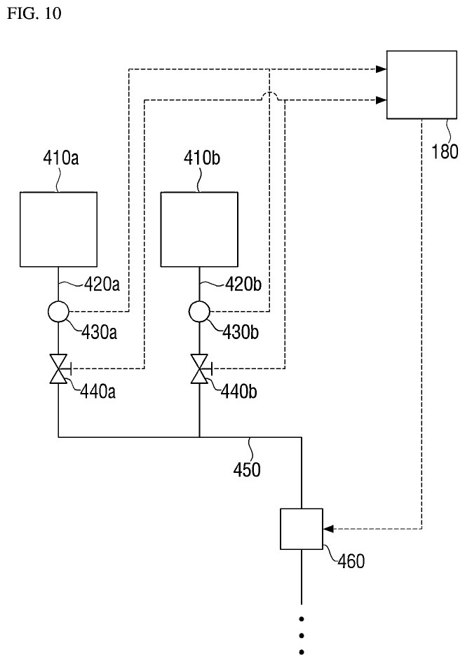

For example, referring to FIGS. 9 and 10, if exhaust pressure information for the first and second auxiliary exhaust pipes 420a and 420b is input from the first and second sensors 430a and 430b and it is confirmed that the first and second shutoff valves 440a and 440b are both open for smooth fluid movement in the first and second auxiliary exhaust pipes 420a and 420b, the control unit 180 may control the damper 460 based on the measurement results from the first and second sensors 430a and 430b, i.e., the input exhaust pressure information.

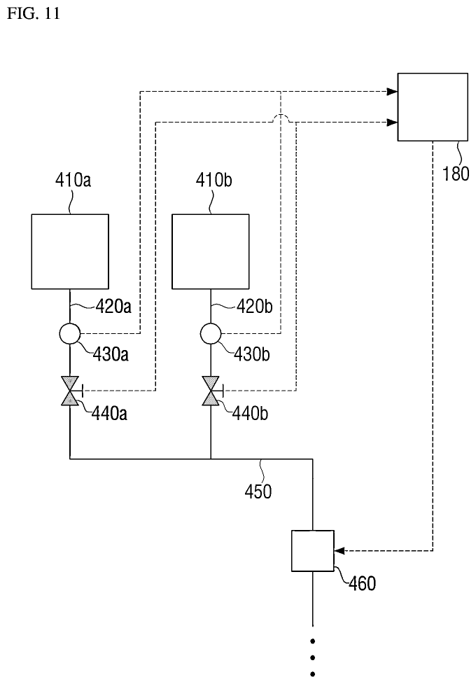

Alternatively, referring to FIGS. 9 and 11, if the exhaust pressure information for the first and second auxiliary exhaust pipes 420a and 420b is input from the first and second sensors 430a and 430b and it is confirmed that the first and second shutoff valves 440a and 440b are both closed, the control unit 180 may also control the damper 460 based on the measurement results from the first and second sensors 430a and 430b, i.e., the input exhaust pressure information.

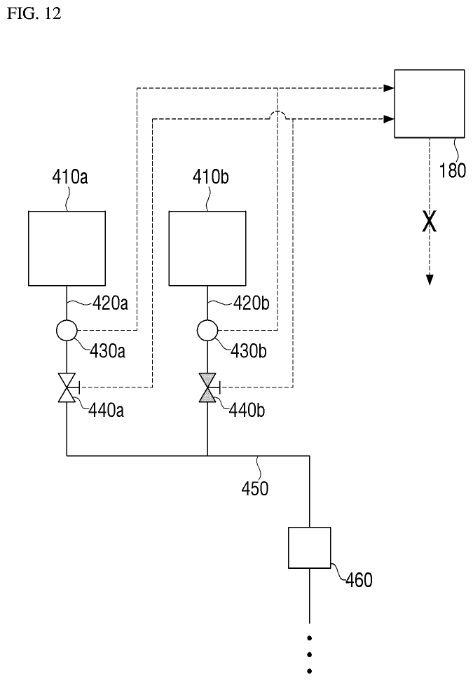

Yet alternatively, referring to FIGS. 9 and 12, if the exhaust pressure information for the first and second auxiliary exhaust pipes 420a and 420b is input from the first and second sensors 430a and 430b and it is confirmed that the first shutoff valve 440a is open but the second shutoff valve 440b is closed, the control unit 180 may not control the damper 460.

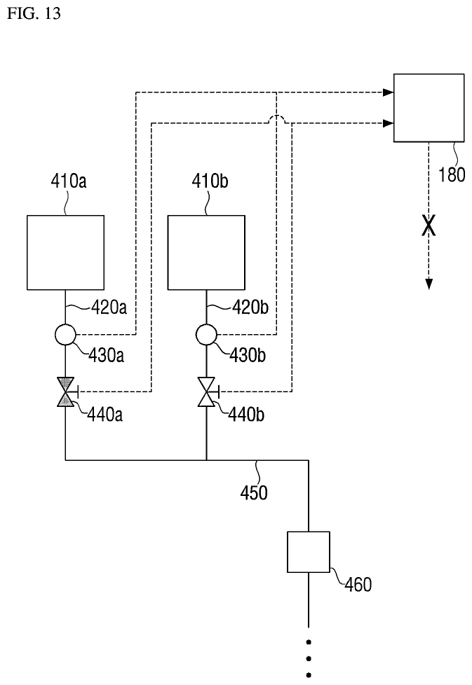

Still alternatively, referring to FIGS. 9 and 13, if the exhaust pressure information for the first and second auxiliary exhaust pipes 420a and 420b is input from the first and second sensors 430a and 430b and it is confirmed that the second shutoff valve 440b is open but the first shutoff valve 440a is closed, the control unit 180 may also not control the damper 460.

In summary, the control unit 180 may control the damper 460 based on the measurement results from the first and second sensors 430a and 430b, which are installed in the first and second auxiliary exhaust pipes 420a and 420b, if it is confirmed that the first and second shutoff valves 440a and 440b are in the same state, as in the examples of FIGS. 10 and 11. Alternatively, if it is confirmed that the first and second shutoff valves 440a and 440b are in different states, as in the examples of FIGS. 12 and 13, the control unit 180 may not control the damper 460 based on the measurement results from the first and second sensors 430a and 430b.

FIG. 9 is a second exemplary schematic view illustrating explaining the role of the control unit that constitutes the semiconductor manufacturing equipment with a plurality of process chambers. FIG. 10 is a third exemplary schematic view illustrating the role of the control unit that constitutes the semiconductor manufacturing equipment with a plurality of process chambers. FIG. 11 is a fourth exemplary schematic view illustrating the role of the control unit that constitutes the semiconductor manufacturing equipment with a plurality of process chambers. FIG. 12 is a fifth exemplary schematic view illustrating the role of the control unit that constitutes the semiconductor manufacturing equipment with a plurality of process chambers. FIG. 13 is a sixth exemplary schematic view illustrating the role of the control unit that constitutes the semiconductor manufacturing equipment with a plurality of process chambers.

When the control unit 180 controls the damper 460, which is installed in the main exhaust duct based on the exhaust volumes measured from the individual exhaust ducts connected to the respective units, the control unit 180 may selectively control the damper 460 to prevent interference between exhausts from different units, depending on whether the process stages in the units are identical. If the units are substrate treating apparatuses of the same type, the damper 460 may be selectively controlled based on whether the process stages in the units are identical.

In other words, in the case of controlling the damper 460 based on the measurement results from the first and second sensors 430a and 430b, which are installed in the first and second auxiliary exhaust pipes 420a and 420b, if it is confirmed that the process stages in the first and second units 410a and 410b are identical, the control unit 180 may control the damper 460 based on the measurement results from the first and second sensors 430a and 430b. Alternatively, if it is confirmed that the process stages in the first and second units 410a and 410b are different, the control unit 180 may not control the damper 460 based on the measurement results from the first and second sensors 430a and 430b.

As stated above, the term “process stage” refers to a stage in each process. For example, the stages of a coating process may include positioning the substrate W onto a substrate support unit 310, supplying a treating solution onto the substrate W using the spraying unit 340, rotating the substrate W using the spin head 311, raising the substrate support unit 310 depending on the type of treating solution supplied by the spray unit 340, and recovering the treating solution through the treating solution recovery module 320. Since the amount of exhaust gas discharged through each exhaust duct may vary from one stage to another stage of each process, the damper 460 may be selectively controlled depending on whether the process stages in the first and second units 410a and 410b are identical.

Conversely, even if the units are at different process stages but discharge the amount of exhaust gas, it may considered that the units are at the same process stage, and selective control of the damper 460 may be performed accordingly.

The control unit 180 may automatically control the damper 460 as previously described. Specifically, the control unit 180 may control the damper 460 using multiple exhaust pressure sensors, i.e., the first and second sensors 430a and 430b. Also, the control unit 180 may selectively control the damper 460 depending on the status of the units. In this manner, the control unit 180 can maintain a constant exhaust pressure in each exhaust duct, i.e., each of the first auxiliary exhaust pipe 420a, the second auxiliary exhaust pipe 420b, and the main exhaust pipe 450.

The control unit 180 can control the damper 460 by receiving exhaust pressures from multiple units via multiple exhaust pressure sensors, and can automatically control the main exhaust pressure. Accordingly, the control unit 180 can control the pressure for each unit at a constant ratio.

Furthermore, the control unit 180 can utilize status information of multiple units to control the damper 460. That is, the control unit 180 can determine when to control the damper 460 based on the statuses of the multiple units. The control unit 180 can control only when the units are under the same process conditions, as described with reference to FIGS. 9 through 13.

It has been described so far how the control unit 180 controls two units, i.e., the first and second units 410a and 410b. However, as previously mentioned, the control unit 180 can control more than two units, for example, three or more units. An example in which the control unit 180 controls three units, i.e., first, second, and third units 410a, 410b, and 410c, will hereinafter be described.

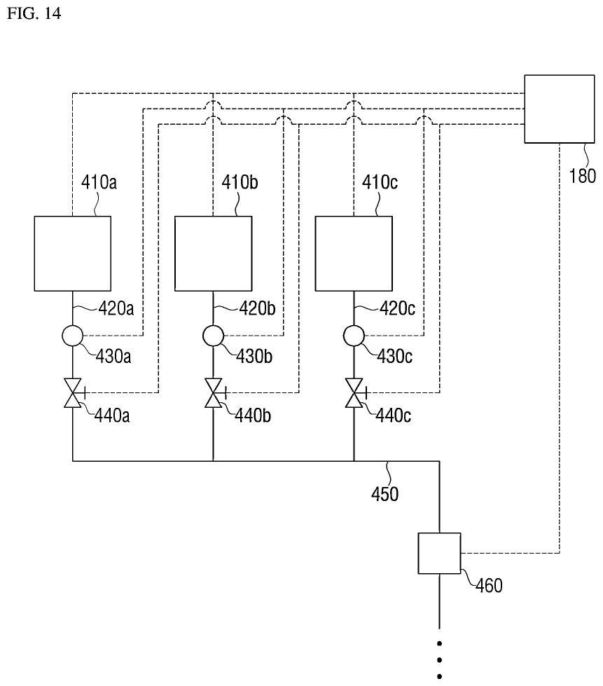

Specifically, only the differences between when controlling two units, i.e., the first and second units 410a and 410b, and when controlling three units, i.e., the first, second, and third units 410a, 410b, and 410c, will hereinafter be described. FIG. 14 is a third exemplary schematic view illustrating the control unit that constitutes the semiconductor manufacturing equipment with multiple process chambers.

Referring to FIG. 14, the first, second, and third units 410a, 410b, and 410c may be process chambers of different types, but the present disclosure is not limited thereto. Alternatively, the first, second, and third units 410a, 410b, and 410c may also be process chambers of the same type. Alternatively, the first, second, and third units 410a, 410b, and 410c may be different modules within the same process chamber.

Alternatively, some of the first, second, and third units 410a, 410b, and 410c may be process chambers of the same type, and the other units may be process chambers of different types. For example, the first unit 410a may be a substrate treating apparatus 150a, the second unit 410b may be one of two substrate treating apparatuses 150b, and the third unit 410c may be the other second substrate treating apparatus 150b.

When the control unit 180 controls three units, i.e., the first, second, and third units 410a, 410b, and 410c, the first, second, and third units 410a, 410b, and 410c may be individually connected to their respective exhaust pipes. The first unit 410a may be connected to a first auxiliary exhaust pipe 420a, the second unit 410b may be connected to a second auxiliary exhaust pipe 420b, and the third unit 410c may be connected to a third auxiliary exhaust pipe 420c.

The control unit 180 may control sensors installed in the respective exhaust pipes. Specifically, the control unit 180 may control first, second, and third sensors 430a, 430b, and 430c, which are installed in the first, second, and third auxiliary exhaust pipes 420a, 420b, and 420c, respectively. The first, second, and third sensors 430a, 430b, and 430c may be sensors performing the same function. The first, second, and third sensors 430a, 430b, and 430c may be sensors measuring exhaust pressure.

The control unit 180 may also control valves installed in the respective exhaust pipes. Specifically, the control unit 180 may control first, second, and third shutoff valves 440a, 440b, and 440c, which are installed in the first, second, and third auxiliary exhaust pipes 420a, 420b, and 420c, respectively. The first, second, and third shutoff valves 440a, 440b, and 440c may be valves performing the same function. The first, second, and third shutoff valves 440a, 440b, and 440c may be valves opening or closing the first, second, and third auxiliary exhaust pipes 420a, 420b, and 420c, respectively.

As previously described, the control unit 180 may control the first and second units 410a and 410b and may receive process status information from the first and second units 410a and 410b. Similarly, the control unit 180 may control the third unit 410c and may receive process status information from the third unit 410c.

Additionally, the control unit 180 may control the first and second sensors 430a and 430b and may receive information regarding the pressures of the fluids flowing through the first auxiliary exhaust pipes 420a and 420b from the first and second sensors 430a and 430b. Similarly, the control unit 180 may control the third sensor 430c and may receive information regarding the pressure of the fluid flowing through the third auxiliary exhaust pipe 420c from the third sensor 430c.

Also, the control unit 180 may control the first shutoff valve 440a, the second shutoff valve 440b, and the main valve 460 and may receive valve status information from the first shutoff valve 440a, the second shutoff valve 440b, and the main valve 460. Similarly, the control unit 180 may control the third shutoff valve 440c and may receive valve status information from the third shutoff valve 440c.

When the control unit 180 controls three units, i.e., the first, second, and third units 410a, 410b, and 410c, the control unit 180 may control the damper 460 based on the measurement results from the first, second, and third sensors 430a, 430b, and 430c, which are installed in the first, second, and third auxiliary exhaust pipes 420a, 420b, and 420c, respectively.

In this manner, the control unit 180 may control the flow rate of the fluid flowing through the main exhaust pipe 450.

When the control unit 180 controls the damper 460 based on the measurement results from the first, second, and third sensors 430a, 430b, and 430c, which are installed in the first, second, and third auxiliary exhaust pipes 420a, 420b, and 420c, respectively, the control unit 180 may utilize information regarding the first, second, and third shutoff valves 440a, 440b, and 440c.

In such cases, if it is confirmed that the first, second, and third shutoff valves 440a, 440b, and 440c are all in the same status regarding whether they are open or closed, the control unit 180 may control the damper 460 based on the measurement results from the first, second, and third sensors 430a, 430b, and 430c.

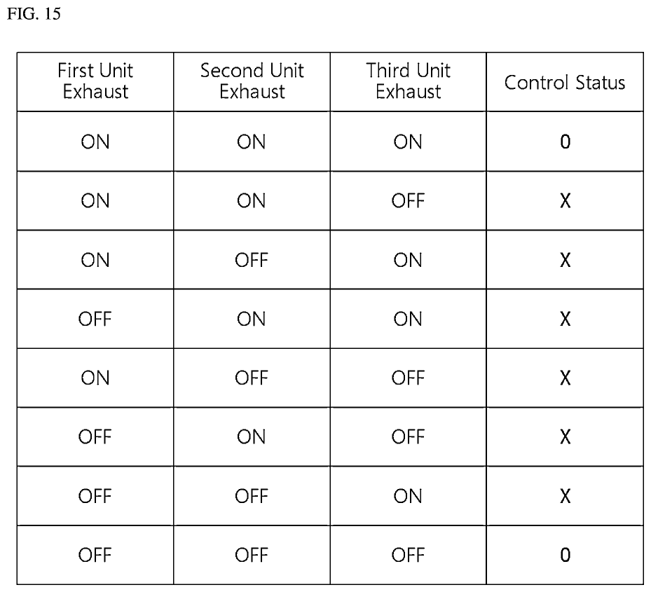

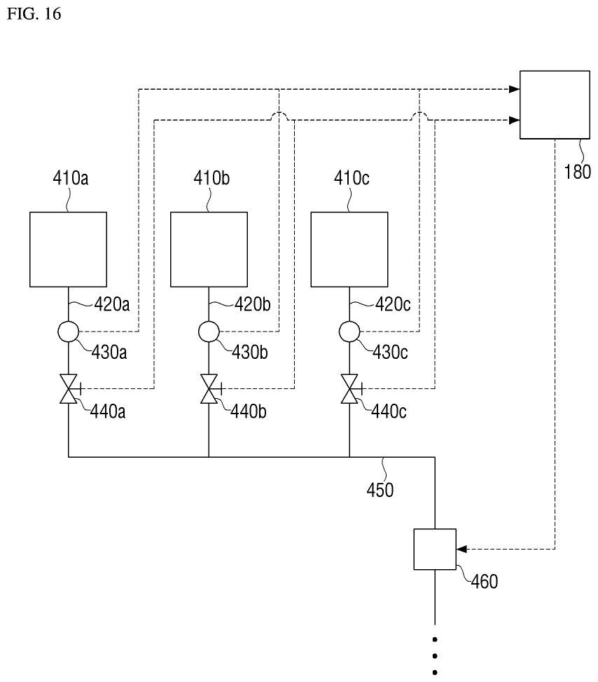

For example, as illustrated in FIGS. 15 and 16, if the exhaust pressure information for the first, second, and third auxiliary exhaust pipes 420a, 420b, and 420c, respectively, is received from the first, second, and third sensors 430a, 430b, and 430c and it is confirmed that the first, second, and third shutoff valves 440a, 440b, and 440c are all open, the control unit 180 may control the damper 460 based on the received exhaust pressure information.

Conversely, if it is confirmed that one of the first, second, and third shutoff valves 440a, 440b, and 440c is in a different status from the other shutoff valves, the control unit 180 may not control the damper 460 based on the measurement results from the first, second, and third sensors 430a, 430b, and 430c.

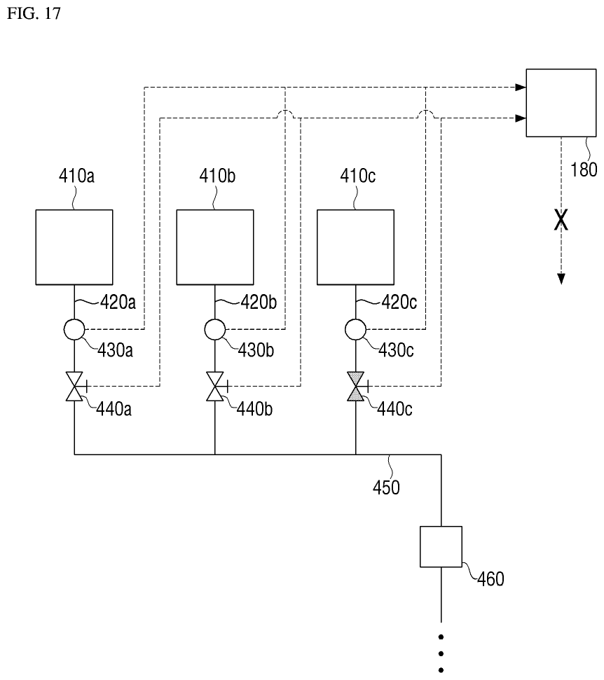

For example, as illustrated in FIGS. 15 and 17, if exhaust pressure information for the first, second, and third auxiliary exhaust pipes 420a, 420b, and 420c is received from the first, second, and third sensors 430a, 430b, and 430c, respectively, and it is confirmed that the first and second shutoff valves 440a and 440b are open while the third shutoff valve 440c is closed, the control unit 180 may not control the damper 460 based on the measurement results from the first, second, and third sensors 430a, 430b, and 430c.

FIG. 15 is a seventh exemplary schematic view illustrating the role of the control unit that constitutes the semiconductor manufacturing equipment with a plurality of process chambers. FIG. 16 is an eighth exemplary schematic view illustrating the role of the control unit that constitutes the semiconductor manufacturing equipment with a plurality of process chambers. FIG. 17 is a ninth exemplary schematic view illustrating the role of the control unit that constitutes the semiconductor manufacturing equipment with a plurality of process chambers.

When the control unit 180 controls the damper 460 based on the measurement results from the first, second, and third sensors 430a, 430b, and 430c, which are installed in the first, second, and third auxiliary exhaust pipes 420a, 420b, and 420c, respectively, the control unit 180 may control the damper 460 based on the measurement results from the first, second, and third sensors 430a, 430b, and 430c if it is confirmed that all the first, second, and third units 410a, 410b, and 410c are operating at the same process stage.

Conversely, if it is confirmed that one of the first, second, and third units 410a, 410b, and 410c is operating at a different process stage, the control unit 180 may not control the damper 460 based on the measurement results from the first, second, and third sensors 430a, 430b, and 430c.

Alternatively, if it is confirmed that the first, second, and third units 410a, 410b, 410c are all operating at different process stages, the control unit 180 may not control the damper 460 based on the measurement results from the first, second, and third sensors 430a, 430b, and 430c.

The effects that the semiconductor manufacturing equipment 100 can achieve through the above-described functions of the control unit 180 are as follows.

First, the semiconductor manufacturing equipment 100 can consistently maintain exhaust pressure through automatic control.

Second, by controlling the damper 460 using the exhaust pressure from multiple units, the semiconductor manufacturing equipment 100 can prevent abnormal exhaust pressure supply from each unit.

Third, even if exhaust pressure changes occur due to different process stages between different units, the semiconductor manufacturing equipment 100 can prevent abnormal pressure control.

Fourth, by maintaining a consistent exhaust pressure, a stable process operation is enabled.

Embodiments of the present disclosure have been described above with reference to the accompanying drawings, but the present disclosure is not limited thereto and may be implemented in various different forms. It will be understood that the present disclosure can be implemented in other specific forms without changing the technical spirit or gist of the present disclosure. Therefore, it should be understood that the embodiments set forth herein are illustrative in all respects and not limiting.

What is claimed is:

1. Semiconductor manufacturing equipment comprising:
a damper installed in a main exhaust pipe;
a first unit treating a substrate and connected to the main exhaust pipe through a first auxiliary exhaust pipe;
a second unit treating the substrate and connected to the main exhaust pipe through a second auxiliary exhaust pipe; and
a control unit controlling the first and second units,
wherein the control unit controls the damper based on exhaust volumes from the first and second units.

2. The semiconductor manufacturing equipment of claim 1, further comprising:
a first sensor installed in the first auxiliary exhaust pipe; and
a second sensor installed in the second auxiliary exhaust pipe,
wherein the control unit controls the damper based on measurement values from the first and second sensors.

3. The semiconductor manufacturing equipment of claim 2, further comprising:
a first shutoff valve installed in the first auxiliary exhaust pipe; and
a second shutoff valve installed in the second auxiliary exhaust pipe.

4. The semiconductor manufacturing equipment of claim 3, wherein the control unit selectively controls the damper based on whether the first and second shutoff valves are open or closed.

5. The semiconductor manufacturing equipment of claim 4, wherein the control unit controls the damper if the first and second shutoff valves have the same status regarding whether they are open or closed.

6. The semiconductor manufacturing equipment of claim 4, wherein the control unit does not control the damper if the first and second shutoff valves have different statuses regarding whether they are open or closed.

7. The semiconductor manufacturing equipment of claim 3, wherein
the first sensor is disposed between the first unit and the first shutoff valve, and
the second sensor is disposed between the second unit and the second shutoff valve.

8. The semiconductor manufacturing equipment of claim 2, wherein the first and second sensors measure pressure based on exhaust volume.

9. The semiconductor manufacturing equipment of claim 1, wherein the first and second units are substrate treating apparatuses of different types or of the same type.

10. The semiconductor manufacturing equipment of claim 1, wherein the control unit selectively controls the damper depending on statuses of the first and second units.

11. The semiconductor manufacturing equipment of claim 1, wherein the control unit determines when to control the damper based on statuses of the first and second units.

12. The semiconductor manufacturing equipment of claim 1, wherein if the first and second units are substrate treating apparatuses of the same type, the control unit selectively controls the damper based on whether the first and second units are at the same process stage.

13. The semiconductor manufacturing equipment of claim 12, wherein the control unit controls the damper if the first and second units are at the same process stage.

14. The semiconductor manufacturing equipment of claim 12, wherein the control unit does not control the damper if the first and second units are at different process stages.

15. The semiconductor manufacturing equipment of claim 1, wherein the control unit controls exhaust pressures of the first and second units at a predetermined ratio.

16. A control unit for controlling first and second units,
wherein
the first unit treats a substrate and is connected to a damper, which is installed in a main exhaust pipe through a first auxiliary exhaust pipe,
the second unit treats the substrate and is connected to the damper, which is also connected to the main exhaust pipe through a second auxiliary exhaust pipe,
the control unit receives pressure resulting from an exhaust volume of the first unit from a first sensor, which is installed in the first auxiliary exhaust pipe,
the control unit receives pressure resulting from an exhaust volume of the second unit from a first sensor, which is installed in the second auxiliary exhaust pipe, and
the control unit controls the damper based on the received pressures.

17. The control unit of claim 16, wherein the control unit selectively controls the damper based on whether first and second shutoff valves, which are installed in the first and second auxiliary exhaust pipes, respectively, are open or closed.

18. The control unit of claim 17, wherein the control unit controls the damper if the first and second shutoff valves have the same status regarding whether they are open or closed, and does not control the damper if the first and second shutoff valves have different statuses regarding whether they are open or closed.

19. The control unit of claim 16, wherein the control unit selectively controls the damper based on statuses of the first and second units or whether the first and second units are at the same process stage.

20. Semiconductor manufacturing equipment comprising:
a damper installed in a main exhaust pipe;
a first unit treating a substrate and connected to the main exhaust pipe through a first auxiliary exhaust pipe;
a second unit treating the substrate and connected to the main exhaust pipe through a second auxiliary exhaust pipe;
a first shutoff valve installed in the first auxiliary exhaust pipe;
a second shutoff valve installed in the second auxiliary exhaust pipe;
a first sensor installed in the first auxiliary exhaust pipe and disposed between the first unit and the first shutoff valve;
a second sensor installed in the second auxiliary exhaust pipe and disposed between the second unit and the second shutoff valve; and
a control unit controlling the first and second units,
wherein
the control unit controls the damper based on pressures resulting from exhaust volumes measured from the first and second units by the first and second sensors, respectively,
the control unit selectively controls the damper based on whether the first and second shutoff valves are open or closed, and
the control unit controls the damper if the first and second shutoff valves have the same status regarding whether they are open or closed, and does not control the damper if the first and second shutoff valves have different statuses regarding whether they are open or closed.
